(19) United States
(12) Patent Application Publication
(10) Pub. No.: US 2013/0192663 A1
(43) Pub. Date: Aug. 1, 2013

(54) SINGLE AND MULTI-JUNCTION LIGHT AND CARRIER COLLECTION MANAGEMENT CELLS

(71) Applicants: Stephen J. Fonash, State College, PA (US); Wook Jun Nam, State College, PA (US)

(72) Inventors: Stephen J. Fonash, State College, PA (US); Wook Jun Nam, State College, PA (US)

(21) Appl. No.: 13/823,929

(22) PCT Filed: Sep. 15, 2011
(86) PCT No.: PCT/US11/51804

§ 371 Date: Mar. 15, 2013

Related U.S. Application Data
(60) Provisional application No. 61/383,289, filed on Sep. 15, 2010.

(51) Int. Cl. H01L 31/052

(52) U.S. Cl. CPC H01L 31/0527
USPC 136/246; 136/256

(57) ABSTRACT

A material design is provided for a light and carrier collection (LCCM) architecture in single junction and multi-junction photovoltaic and light sensor devices. The LCCM architecture improves performance and, when applied to single or multi-junctions, can lead to solar cells on flexible plastic substrates which can be easily deployed and even draped over various shapes and forms. The device has an array of conducting nano-elements in electrical and physical contact with the planar electrode. A spacer of 0 to 100 nm in thickness may be used to contact the array of conducting nano-elements. One or more volume regions comprised of at least one light absorbing material is present with the first in simultaneous contact with said spacer to form an operating photovoltaic single- or multi-junction device with periodic undulations to enhance trapping of the impinging light and photocarrier collection throughout the absorber volume regions.

### RELATED APPLICATIONS

This application claims priority benefit of U.S. provisional application Ser. No. 61/383,289 filed 15 Sep. 2010, the content of which is hereby incorporated by reference.

### FIELD OF INVENTION

The field of invention is photovoltaic devices for energy conversion. The invention is directed to the use of the light and carrier collection architecture in single junction and multi-junction photovoltaic devices. The invention focuses on an incoming solar spectrum and is therefore interested in, but not limited to, solar cell photovoltaic devices. The structures of this invention can also be used to convert an incoming spectrum into chemical energy (e.g., via photolysis) and can also be used for light detection devices.

### BACKGROUND OF INVENTION

Developing photovoltaic (PV) cells that can convert an incoming solar light spectrum more fully into electrical power is a very daunting task [1, 2]. Single junction cells are utilized but light is usually not effectively trapped in the cells and the absorber material thickness is chosen to try to compensate for this problem. In addition, when single junction solar cells are used, only part of the incoming spectrum is utilized, as determined by the absorber band gap, Multi-junction solar cells are also employed so that the absorber band gaps of the various cells can be matched to the solar spectrum [3]. Such multi-junction solar cells do yield the highest power conversion efficiencies (PCE) but they are expensive. The magnitude of the problems can be put into perspective by noting that complex concentrator-based multi-junction cells, which utilize compound semiconductor absorber materials and are fabricated using demanding molecular beam epitaxy (MBE) or metal organic chemical vapor deposition (MOCVD) techniques, are able to attain ˜44% PCE values—and only for short periods of time—due to intense heating [1]. Recently Sharp Corporation announced that they have been able to attain 35.8% PCE values for multi-junction III-V compound semiconductor cells and that they were able to do so without concentration [2]. This is significant since concentrators add costs and complexity to PV energy conversion. The triple junction compound semiconductor cell used by Sharp in their work is depicted in FIG. 1. However, the Sharp device uses epitaxial deposition methods as opposed to less expensive thin film deposition methods. While the former generally results in very high quality material and the latter in polycrystalline or amorphous material, the costs of epitaxial deposition methods are prohibitive for large area solar cell applications.

Full spectrum thin film multi-junction solar cells which do not employ concentration have been explored by a number of groups and these efforts have included cells based on a-Si:H and a-SiGe:H [4], a-Si:H and nc-Si:H [5,6], and chalcogenide compound semiconductors [7]. Owing to the material costs and complexity of construction, these cells have met with limited acceptance.

Thus, there exists a need for a novel collection architecture that overcomes the aforementioned problems associated with the prior art.

### SUMMARY OF INVENTION

A material design is provided for a light and carrier collection (LCCM) architecture in single junction and multi-junction photovoltaic devices. The LCCM architecture improves performance and, when applied to single or multi-junctions, can lead to solar cells on flexible plastic substrates which can be easily deployed and even draped over various shapes and forms. Unlike the expensive fabrication techniques used for the Sharp multi-junction cell, the LCCM approach allows thin film, multi-junction structures. These devices do not require concentration configurations.

The novel LCCM architecture uses conducting nano-elements for carrier collection and for creating photonic structures for light trapping. A superstrate device is provided that has a planar electrode, and an array of conducting nano-elements in electrical and physical contact with the planar electrode. A spacer may be in contact with the array of conducting nano-elements. A region having at least one photonic absorbing layer contains an absorber volume region or regions and is in simultaneous contact with said spacer or directly with the array of nano-elements to form an operating photovoltaic device or single- or multi-junction device with periodic undulations. A distal reflecting counter electrode relative to the direction of impinging light; is provided wherein the photovoltaic device enhances trapping of the impinging light and photocarrier collection throughout the absorber volume regions.

A substrate device is provided that has a planar electrode comprising a reflecting material and an array of conducting nano-elements in electrical and physical contact with said planar electrode. A spacer may be in contact with the array of conducting nano-elements. A region having at least one photonic absorbing layer contains an absorber volume region or regions and is in simultaneous contact with said spacer or directly with the array of nano-elements to form an operating photovoltaic device or single- or multi-junction device with periodic undulations. Said substrate device enhances trapping of the impinging light and photocarrier collection throughout the absorber volume regions.

### BRIEF DESCRIPTION OF THE DRAWINGS

FIG. 1. Schematic of a prior art Sharp multi-junction cell structure. This structure has attained 35.8% PCE without concentration [2]. Light enters from the top of the structure.

FIGS. 2A and 2B. A. Schematic showing the substrate LCCM architecture being applied to a single junction a-Si:H solar cell. The device is shown in cross-section. Light enters through the free (air/cell) surface. B. Schematic showing the superstrate LCCM architecture being applied to a single junction a-Si:H solar cell. The device is shown in cross-section. Light enters through a glass (shown) or plastic substrate.

FIG. 3. A field emission scanning electron micrograph (FESEM) of the cross-section of a superstrate a-Si:H single junction LCCM cell. The cross-section was prepared using focused ion beam (FIB) milling.

FIG. 4. The unit cell of a two-junction cell substrate LCCM (non-planar) multi-junction cell. The inter-cell electrical and optical matching structure is shown in this schematic. The initial parameters used in the design simulation were R=200 nm, R*=150 nm, d=100 nm, H=550 nm, t=200 nm, and t*=150 nm with an electrical and optical matching structure of 5 nm AZO on 5 nm of Ag on 5 nm of AZO.

FIG. 5. Absorption as a function of wavelength for a nano-crystalline silicon (nc-Si) superstrate single junction LCCM structure, as seen in FIGS. 2A and 2B, and for its corresponding nc-Si planar structure. The LCCM design modeled here utilizes nc-Si instead of a-Si. In both cases the nc-Si has been deposited to give the same nominal 400 nm thickness on a planar surface. The spacing (inter-electrode element distance) in this particular nano-structure is 800 nm and the radius of the hemispherical-like structures is 150 nm. The optical properties of the materials are fully accounted for by using the complex index of refraction, as determined by variable angle spectroscopic ellipsometry.

FIG. 6. Substrate Configuration 1 J_{SC} and AMD behavior as a function of L for 5 or 30 nm AZO ET/HBLs on Ag. The curves are intended to guide the eye. The nano-elements are columns and R=200, R*=150, t=200, H=550, and d=100 nm define the unit cell employed in the modeling. Adjacent unit cells touch if L=L_{touch} and are truncated if L<L_{touch}.

FIG. 7. Substrate Configuration 2 J_{SC} and AMD behavior as a function of L. The curves are intended to guide the eye. The nano-elements are columns composed of a 5 nm AZO (ET/HBL) film on an Ag coated SiO₂ core. This configuration also has a 5 nm or 30 nm AZO layer on the Ag between columns. R=200, R*=150, t=200, H=550, and d=90 nm define the unit cell employed in the modeling. Adjacent unit cells touch if L=L_{touch} and are truncated if L<L_{touch}.

FIG. 8. Substrate Configuration 3 J_{SC} and AMD behavior as a function of L for two values of H. The curves are intended to guide the eye. The nano-elements are AZO cones sitting on 30 nm AZO layer on Ag. R=200, R*=150, t=200, H=350 or 550, and d=100 nm define the unit cell employed in the modeling. Adjacent unit cells touch if L=L_{touch} and are truncated if L<L_{touch}.

FIG. 9. An inter-cell electrical and optical matching structure utilizing a Bragg stack for selective reflection. Such structures can be designed to be able to reflect a specified bandwidth. When using this structure in a LCCM a-Si:H device in tandem with a planar nc-Si device, the structure would be optimally designed to reflect light, which reaches the inter-cell region and has supra a-Si:H band gap photons (i.e., ˜1.8 ev for our a-Si:H), back into the a-Si:H, Light with photons whose energy is less than ˜1.8 ev would pass into the back nc-Si cell. The degree to which this structure is able to reflect a specified bandwidth increases with the number of layers. Here a four layer structure is shown.

FIG. 10. Absorption in the a-Si:H and in the nc-Si absorbers of the LCCM tandem structure of FIG. 10, as a function of the nano-element spacing L. Also shown is the loss due to absorption in the Ag present in the mixed layer and at the cell back

FIGS. 11A and 11B. Absorption as determined by computer simulations for a single junction a-Si:H LCCM cell and its corresponding planar cell as a function of the light impingement angle with respect to the normal. Part (A) shows 30 degree impingement angle and part (B) shows 60 degree impingement angle results. There has been no attempt here to adjust the nano-structure dimensions (L, h, t, R, etc.) to optimize this behavior.

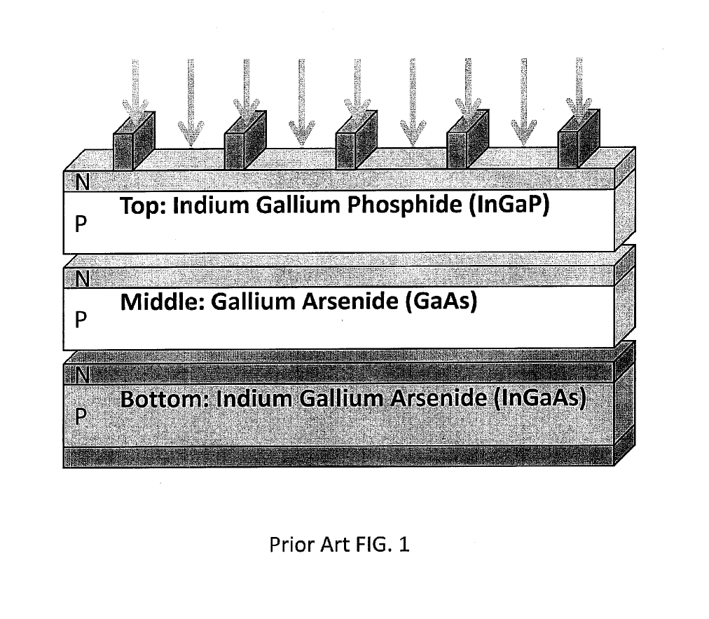

### DETAILED DESCRIPTION OF PREFERRED EMBODIMENTS

The present invention has utility in LCCM single and multi-junction solar cells. In the examples presented, cells are made or modeled or both using silicon-based absorber materials. The present invention is not limited to these absorbers and may be applied to organic (including dye) absorbers as well as to inorganic absorbers including FeS₂, Cu₂ZnSn(Se,S)₄, CIGS, CdTe. III-V semiconductors and their alloys, and lead-based materials.

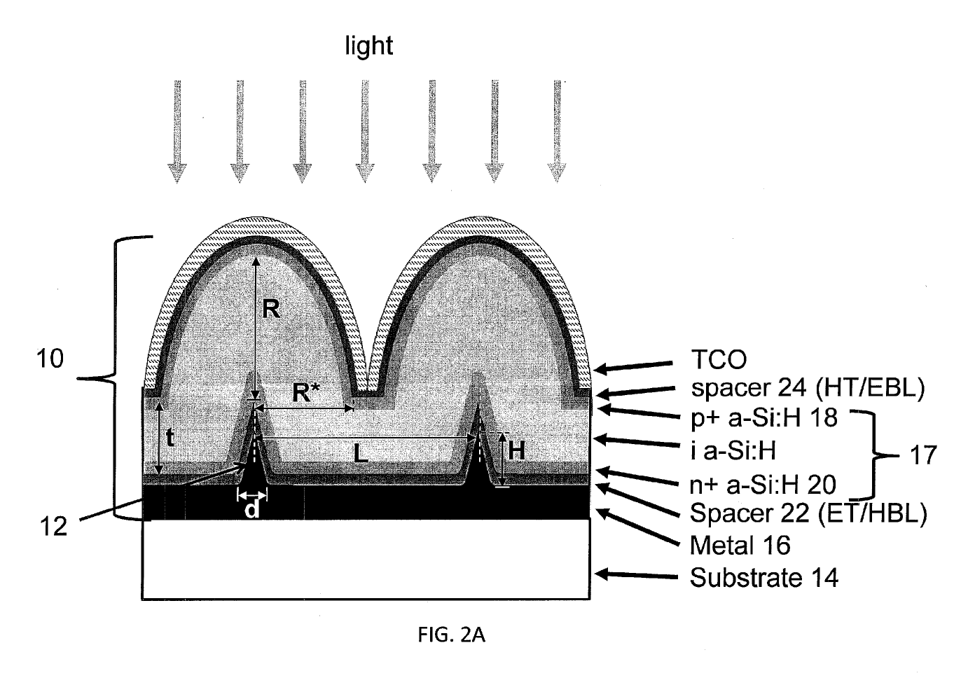

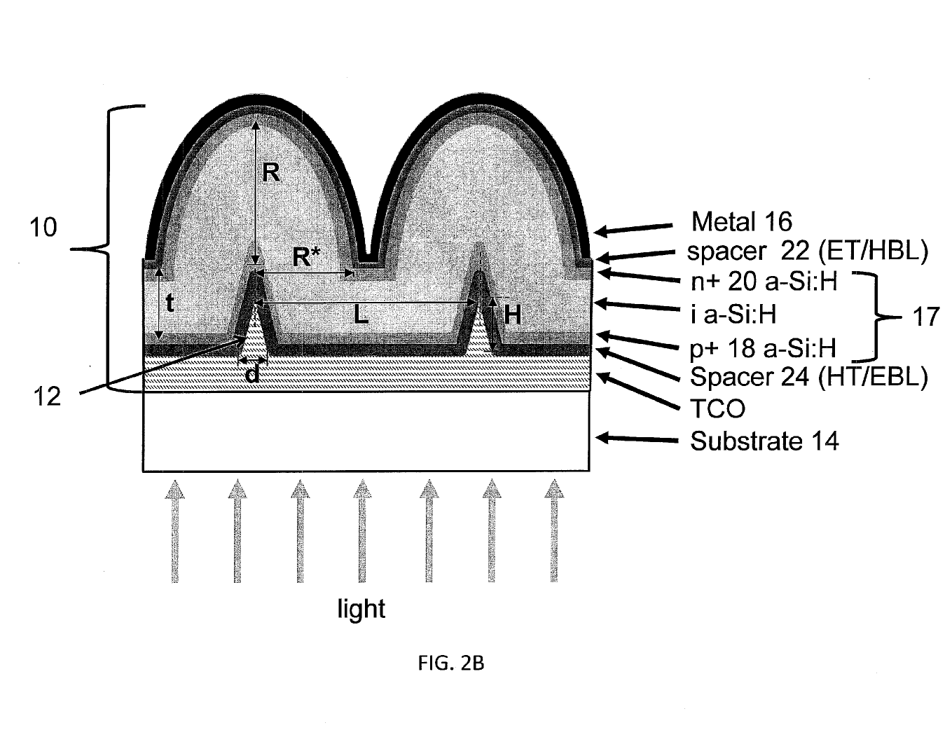

The basic LCCM architectures are in general depicted in the attached schematics for a single junction p-i-n cell yet it is appreciated that the inventive structures are applicable to p-n and surface barrier cells also. These basic architectures are presented schematically in FIGS. 2A and 2B where they are seen to include a two-dimensional array of unit cells 10 with a nano-element 12 at each unit center. Light can enter these arrays either through the substrate 14 (superstrate structure) (FIG. 2B) or through the free surface (substrate structure) (FIG. 2A). In FIGS. 2A and 2B, an electrode array nano-element 12 inherent in each unit cell 10 is seen and a metal (e.g., Ag, Au, Cu and alloys) layer 16 serves as the counter electrode and as a back reflector. Doping of the photonic absorber 17 such as p+layer 18 and/or n+layer 20, spacers 22 and 24 such as ET/HBL and HT/EBL layer, respectively are also optionally provided. The deposited absorber is part of 17 and has a thickness t, the nano-element has a height h, and an inter-electrode element array spacing is L. Carrier collection enhancement is attained by using the nano-elements 12 to ensure that photocarriers in the absorber in 17 are within a collection length of their respective electrodes. Light collection enhancement can be obtained through photonics, plasmonics, and effective absorber thickness phenomena of FIGS. 2A and 2B. The electrode array nano-element 12 inherent in each unit cell is clearly depicted in these figures. It may have a variety of shapes including cone-like and columnar. Also seen is the metal (e.g., Ag), which serves as the counter electrode and as a reflector. Spacer layers 22 and 24 are also shown. These may be present to aid in adjusting the optical electric field distribution—and therefore the absorption and photocarrier generation distributions—as well as to serve as hole blocking/electron transport layers at the cathode (negative voltage) electrode and electron blocking/hole transport layers at the anode (positive voltage) electrode [3]. The LCCM architecture with its repeated (in two-dimensions across the plane of the substrate) unit cell, electrode nano-element array is fabricated by establishing the nano-element pattern on a planar electrode (FIGS. 2A and 2B) and then depositing the absorber containing 17, spacer 22 or 24, and doped layers 18 and 20 in the sequence necessary to order the materials as shown in FIGS. 2A and 2B. The sequential deposition onto the initial nano-element array produces the undulating shape seen in FIGS. 2A and 2B during fabrication and does so without any intervention with selection of processing parameters giving the appropriate conformality. The nano-element array serves to aid in collecting photocarriers from every point in the absorber volume and may serve also as a photonic structure. The nano-element array, or some part thereof, serves as both a structured electrode (for efficient photocarrier collection) and a photonic (and depending on the materials, a plasmonic) structure.

This inventive LCCM architecture is operative for single junction cells and in multi-junction cells. The latter are attained by repeating the required deposition sequences and tailoring inter-cell light reflection and transmission,. A process flow for LCCM single junction cells using a-Si:H as the absorber has resulted in our demonstration of an 8.2% PCE LCCM cell (without antireflection coating), which is the highest PCE reported for any nano-structured solar cell, and our development of a clear pathway to 11% PCE a-Si:H cell technology at $0.80/watt. This price per watt value compares favorably with $2/watt, which is the current best value for the price per watt ratio. The LCCM architecture allows the attainment of this $0.80/watt value for a-Si:H single junction cells because the cell design requires less a-Si:H absorber due to light and carrier collection management thereby saving deposition time and cost. It is important to underscore that the single and multi-junction designs presented herein are, however, in no way limited to a-Si:H. They can be applied to organic (including dye) absorbers as well as to inorganic absorbers including FeS₂, Cu₂ZnSn(Se,S)₄, CIGS, CdTe. III-V semiconductors and their alloys, and lead-based materials.

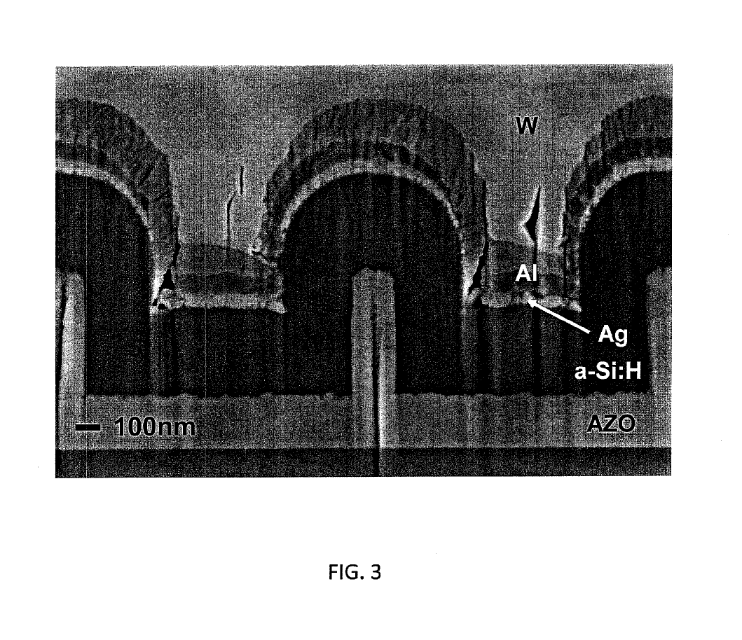

FIG. 3 shows the cross-section of an actual inventive superstrate a-Si:H single junction LCCM cell. In this device, the electrode nano-elements penetrating into the a-Si:H absorber are formed from aluminum-doped zinc oxide (AZO), a well-known transparent conducting oxide (TCO). Other electrode shapes and materials may be used. The array of nano-scale electrode elements seen in FIGS. 2A, 2B, and 3 is basic to the LCCM architecture and constitutes at least a part of one electrode. In the particular device of FIG. 3, the counter electrode is Ag coated with Al. The periodic structure of our LCCM design gives rise to photonic effects (e.g., light trapping and advantageous optical electric field distribution) and can also produce plasmonic phenomenon in the electrode elements, counter electrode, or both, depending on material composition. The arrangement of electrode elements, their height choice, and the absorber thickness choice are picked to insure that photocarriers generated in the absorber are within a collection length of the electrodes.

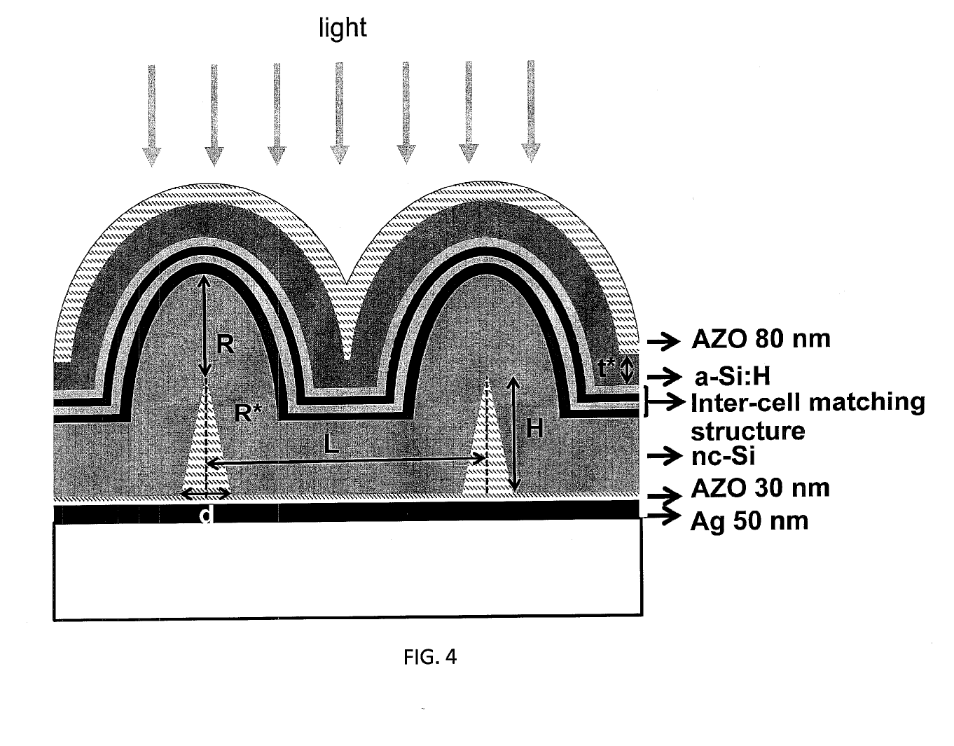

The basic pattern generation process used to produce an actual LCCM structure can be based on techniques such as optical, holographic, nano-imprinting, stamping, probe, nano-sphere, block-copolymer, or beam lithography. The pattern generation process first creates the array of nano-elements. These may be conducting and may be comprised of an inorganic, or organic conductor (e.g., metal, transparent conducting material)) or inorganic, or organic semiconductor. These nano-elements may be created by directly depositing them as an “ink” using a nano-probe technique. In fact, as will be described, conducting cone-like nano-elements disposed on Ag are a very effective substrate LCCM design and such an array may be made with this “nano-ink” approach of pattern generation. These nano-elements may be created by imprinting a pattern into an organic conductor, as an example. They may be created by imprinting empty volumes into a resist, using these volumes as templates, and subsequently electro-chemically growing or depositing the electrode element material using the empty volume template. A lift-off step may follow to better define the nano-elements. Alternatively, the deposition of a conductor onto the nano-element exposed material may follow and may even be done to a thickness level to ensure mechanical stability of the nano-element array. The latter can be used in an approach with transfers the nano-element array from an initial substrate to a final substrate for process sequence completion. In any case, disposition of the absorber, its junction forming, and optional spacer materials is then undertaken in the order seen in FIGS. 2A, 2B and 3 and followed by the counter electrode formation, if a single junction cell is the objective. If a two terminal non-planar multi-junction cell is the objective, disposition of the absorber, its junction forming, and optional spacer materials is undertaken in the proper sequencing order as defined in FIGS. 2A, 2B and 3. This is then followed at inter-cell boundary by an inter-cell electrical and optical matching structure. This may be accomplished by the standard tunnel junction formation used in multi-junctions [3] but done with the simultaneous objective of optimizing the light transmission and reflection. This latter objective may be achieved, for example, by creating a Bragg stack structure for the reflection of supra-band gap photons back into the wider band gap absorber. These steps are then repeated. That is, there is a repetition of the absorber, its junction forming, and optional spacer materials depositions sequenced as defined in FIGS. 2A, 2B and 3. The electrical and optical matching structure formation and subsequent absorber, junction forming, and optional spacer materials depositions are done as many times as is necessary for a non-planar multi-junction cell. The electrical and optical matching structure formation and junction forming materials steps may be designed to be combined. The unit cell of a two-junction non-planar multi-junction is seen in FIG. 4.

Certain single-junction LCCM design rules become apparent from these various examples of single junction superstrate and substrate LCCM solar cells devices. The inventive substrate designs are superior and inter-dome scattering is present in the inventive devices and can be optimized. TCO nano-element or coated nano-element arrays on a metal reflector/electrode (e.g., Ag) give excellent performance. This result is opposite to what is taught in Ref. 6. Inventive devices can be used to simultaneously to: (1) reduce the amount of absorber material used, and (2) enhance PCE. Both advantageously affect the crucial cell cost/watt ratio. Nano-element spacing L in the 400 to 1000 nm range can be optimal, depending on h, d, etc. and are readily determined. This spacing range is easily suited to pattern generation approaches such as optical, holographic, nano-imprinting, stamping, probe, or beam lithography and to roll-to-roll processing. In addition, the roles of nano-element height, back metal, optical spacerET/HBL or HT/EBL layer thickness have been shown to be important. All of this is done utilizing thin films of TCOs and avoiding the use of thicker film, randomly textured TCOs commonly employed in solar cells. All of this can be done in structures for which photogenerated carriers are within a collection length of their collecting electrode.

As noted above, multi-junction LCCM non-planar cells are fabricated by following the design sequencing inherent in the single junction non-planar structure. Multi-junction cells having LCCM non-planar cells on planar cells have the planar cell fabricated and then the LCCM cell is disposed on top of the planar cell. The LCCM architecture applied to multi-junctions gives (1) enhanced absorption in all layers, (2) enhanced long wavelength absorption, (3) the freedom to reduce absorber layer thicknesses (less material is needed), and the ability to employ less stable absorbers in thinner layers. There is another further extremely important point. The collecting electrode elements and thin absorber layer versatility also gives the designer the opportunity to use absorbers with lower carrier mobilities and lifetimes. Finally, FIGS. 12A and 12B point to one more additional advantage of the LCCM approach to single junction and full spectrum multi-junction cells. This figure makes the point that computer simulation shows that a single junction LCCM cell with its nano-structured array is less sensitive to the light impingement angle.

Still another advantage of the LCCM architecture for single and multi-junction solar cells can be seen by directly comparing this approach to light management versus that of transparent conductive oxide (TCO) texturing. This comparison makes the following points:
Texturing is a random process resulting in a range of feature sizes and shapes.
Random texturing can be inherently difficult to control in manufacturing.
Texturing feature sizes can be larger than cell layer thicknesses giving the potential for shorting sites.
The LCCM structure is based on an array layout. It is systematic with no randomness. In the case of non-planar multi-junctions, the systematic array pattern in the bottom cell is transferred to other cells by the fabrication process flow thereby giving a periodic structure in every layer. In the case of the hybrid cell design, the systematic array pattern is only used in the cell disposed onto the planar cell.
With the LCCM architecture, the wavelengths and magnitudes of the Fabry-Perot absorption changes can be advantageously shifted and adjusted by modifying the LCCM design (e.g., by modifying L, R, h, t, and the spacer layers). Such flexibility is not possible in texturing.
   The present invention is further detailed with respect to the following non-limiting examples. These examples should not be construed as limiting the scope of the appended claims.

### EXAMPLE 1

Plasma enhanced chemical vapor deposited (PECVD) a-Si:H was used as the absorber in superstrate single junction structures. Atomic layer deposition (ALD) was first used to coat the indium tin oxide (ITO) on a glass substrate with transparent, conducting aluminum zinc oxide (AZO). This AZO served as an optical spacing layer, as hole transport layer, and as protection for the hydrogen plasma-sensitive ITO during a-Si:H PECVD from silane type gases. These materials are appreciated to be exemplary and that alternative materials with similar optical and electrical properties are readily substituted by a routineer in the art. After applying a template material, void regions were created in the template by standard e-beam lithography-based processing and ALD was used to produce AZO nano-elements in each template void region, thereby resulting in an array of AZO conducting, but transparent nano-elements protruding from the ITO electrode. The array of such nano-elements can be discerned from the FESEM cross-section in FIG. 3. An etch step after ALD was used to remove any AZO which grew onto the exposed template lateral surface and the template material was removed by standard removal procedures. The resulting nano-elements are essentially perpendicular to the ITO planar electrode material. Doped, intrinsic, and again doped PECVD a-Si:H layers were then sequentially deposited onto the nano-element array using PECVD parameters known to produce conformal deposition This was followed by the ALD deposition of an AZO back spacer layer and the deposition of an Ag/Al counter electrode/reflector, as seen in FIG. 3. The superstrate LCCM single junction devices produced in this manner have yielded the highest PCE (8.2%) reported to-date for any nano-structure based a-Si:H cell and this was achieved without any anti-reflection (AR) layer.

The fabrication and modeling expertise that has developed in working with single junction LCCM cells has shown that this architecture is very advantageous also for multi-junction configurations of the present invention. The unit cell of a 2-junction substrate LCCM non-planar multi-junction device is shown in FIG. 4. This figure shows a wider gap material optically in series with a narrower gap back material with light initially entering through the wider gap material at the free surface. Such devices can be a two terminal tandem cell but an also be modified to function as three terminal devices.

### EXAMPLE 2

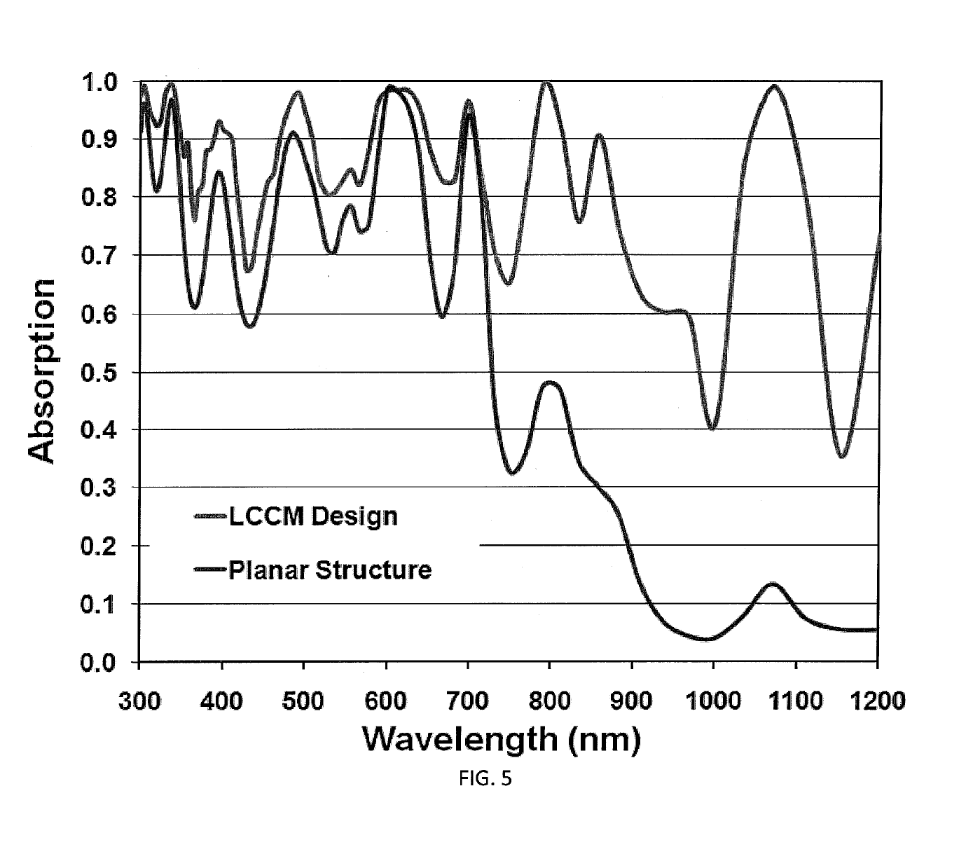

Computer modeling work on both single junction and multi-junction LCCM solar cell structures (a-Si:H, nc-Si:H, and tandem a-Si:H/a-Si(1-x)/Ge(x):H) shows the benefits resulting from the incorporation of nanostructures according to the architecture of this invention (i.e., LCCM approach versus planar controls). In all cases, the LCCM approach outperforms the planar controls. FIG. 5 gives the absorption as a function of wavelength for a single-junction nano-crystalline silicon (nc-Si) superstrate LCCM structure and for the corresponding nc-Si planar structure. These plots are computer modeling results obtained for an inventive design simulated with Maxwell's equations solver software and expertise available at the University of Arkansas (UA). These results are for single junction cells and they drive home an important point: the LCCM architecture greatly enhances absorption, particularly at long wavelengths—and it is doing so in FIG. 5 for a 400 nm nc-Si deposition.

### EXAMPLE 3

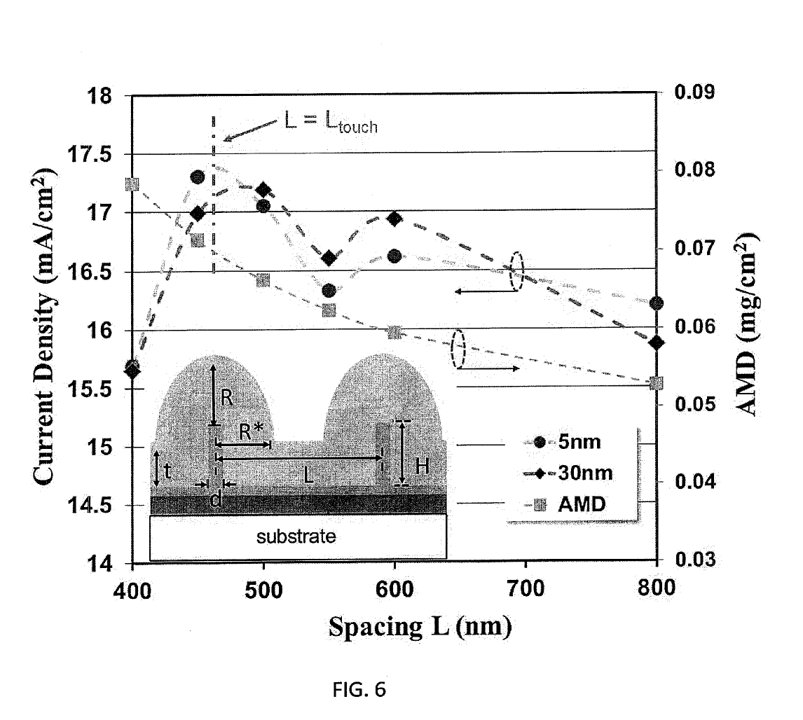

FIG. 6 gives an LCCM substrate Configuration 1 single junction cell which, by definition, has the light entry through the top (80 nm AZO) anode. The cell has 100 nm diameter aluminum zinc oxide (AZO) columns as the nano-elements which are sitting on a cathode composed of 5 or 30 nm of AZO coated onto an opaque planar Ag film. The transport function of this AZO coating is to serve as an electron transport/hole blocking layer (ET/HBL) at the cathode. It also has an optical function, as will emerge in our discussion of the J_{SC} response versus nano-element spacing L obtained from modeling. This response is given in FIG. 6 for the two ET/HBL thicknesses. As seen, J_{SC} decreases with decreasing L for L<L_{touch} and has two maxima in the range L≧L_{touch} one of which is an absolute maximum near L˜L_{touch}. The quantity L_{touch} is the specific L for which the domes just touch. The J_{SC} dependence on L in the L>L_{touch} range present in FIG. 6 is very different from that of superstrate structures where the role of the effective absorber thickness causes J_{SC} to monotonically decrease with increasing L. Interestingly, the J_{SC} behavior for L>L_{touch} in FIG. 6 points to scattering among domes in this Configuration 1 LCCM substrate cell.

The two J_{SC} plots in FIG. 6 point out the sensitivity of the A(λ) behavior to the details of device layer thicknesses and composition. Detailed examination shows that both geometrical scattering and metal scattering, at the cathode, play a role through changes in the long wavelength A(λ) behavior. The former manifests itself most clearly in shifts in the Fabry-Pirot absorption peaks present in A(λ) with changes in the ET/HBL AZO layer thickness. The metal scattering role shows up in the significant reduction in the long wavelength a-Si:H absorption which occurs when Ag is replaced by Al for the 5 nm ET/HBL case. This points to the thinner ET/HBL case, which still has AZO that is thick enough to block hole tunneling at the cathode, allowing an enhanced near-field at the Ag surface to penetrate the absorber more deeply.

The short circuit current density given by modeling a planar control cell with a 200 nm thick a-Si:H absorber is J_{SC}=10.97 mA/cm² and it is 14.08 mA/cm² for a planar control cell with a 750 nm thick a-Si:H absorber. These are useful comparison J_{SC} numbers since the first is for the limiting control planar structure obtained as the spacing L→∞ and the second is for the limiting control planar structure obtained if the absorber had, everywhere, the a-Si:H thickness seen at the peak of the domes in FIG. 6. The superiority of the LCCM configuration can be seen in FIG.6 since J_{SC} exceeds these control values over much of the L range and can attain at least 17.3 mA/cm² for the Configuration 1 architecture.

The full advantage of substrate LCCM approach can be understood by considering an areal mass density (AMD) defined by

AMD=(absorber mass density)×(absorber volume per area of substrate) (1)

Expressing volumes in cm³ and areas in cm² and taking 2210 mg/cm³ as mass density of a-Si:H allows AMD to be calculated in mg/cm² and plotted for Configuration 1 as seen in FIG. 6. Using the J_{SC} and AMD data for Configuration 1 and its controls allows us to determine that the peak J_{SC}=17.3 mA/cm² in FIG. 6 is 58% higher than the attainable with the 200 nm thick planar absorber control and yet the LCCM device uses only 64% more a-Si:H. The latter point follows from noting that the AMD for the LCCM device giving the J_{SC} peak is 0.072 mg/cm² and that for the 200 nm control is 0.044 mg/cm². By comparison, the 750 nm thick planar absorber control has a 28% increase in J_{SC} compared to than that attainable with the 200 nm thick planar absorber control and yet it uses 275% more a-Si:H, since AMD for this control is 0.165 mg/cm². The increase in J_{SC} for the substrate LCCM structure means an increase in PCE. The saving in absorber material for the substrate LCCM structure means savings in deposition time and cost.

### EXAMPLE 4

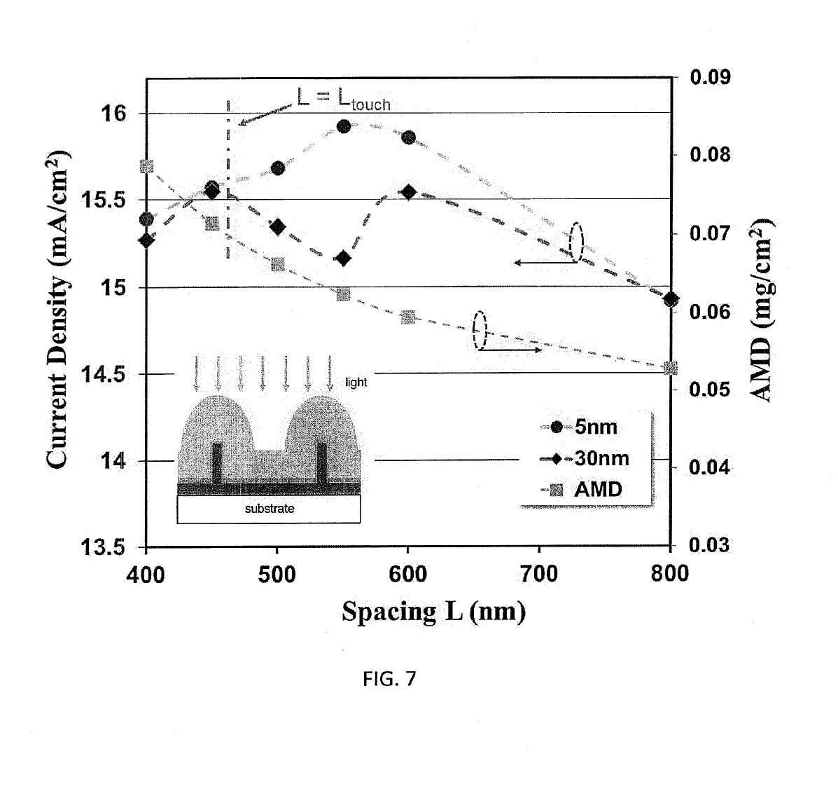

Turning to substrate Configuration 2 seen in FIG. 7, it is seen that this substrate LCCM architecture also uses columns as the nano-elements. These are composed of 5 nm AZO (ET/HBL) film on an Ag coated SiO₂ core. Each of these nano-columns sits on a planar Ag cathode and, in between the nano-columns, there is a 5 nm or 30 nm AZO ET/HBL residing on the planar Ag. While the AMD is the same function of L for both Configurations 1 and 2, the resulting A(λ) plots from our simulation design studies (not shown) for Configuration 2 are inferior to those of Configuration 1 in the middle wavelengths but even more so in the longer wavelengths. The impact of this poorer A(λ) performance on J_{SC} is displayed in FIG. 7 for the two thickness values of the planar inter-column AZO layer. The thinner inter-column AZO layer is seen to improve the J_{SC} capability but not to the level seen in FIG. 6 even though the AMD dependence on L is the same. While the J_{SC} curves of FIG. 7 display an overall dependence on L which is similar to that of FIG. 6, there are two peaks present for the 30 nm but only one for the 5 nm inter-column AZO planar layer. This points to a significant difference in the geometrical scattering interaction taking place when the inter-column AZO layer thickness is changed from 5 to 30 nm. The simulations also suggest there is a metal cathode scattering influence involved in the thinner inter-column AZO case since replacing Ag with Al for the 5 nm AZO inter-column layer reduces the long wavelength A(λ) response (not plotted). Interestingly, the fact that the peak in J_{SC} clearly occurs for L>L_{touch} again points to significant scattering interactions among domes in some substrate LCCM architectures. FIG. 7 shows that J_{SC} exceeds the 200 nm and 750 nm thick planar absorber control values over much of the L range and can attain at least 15.9 mA/cm² with the Configuration 2 architecture. This is not nearly as good as Configuration 1 nor as good as the example presented by Configuration 3. The distinguishing feature of Configuration 2 is that it has an Ag film covering the nano-element. This approach is used in Ref. 9.

### EXAMPLE 5

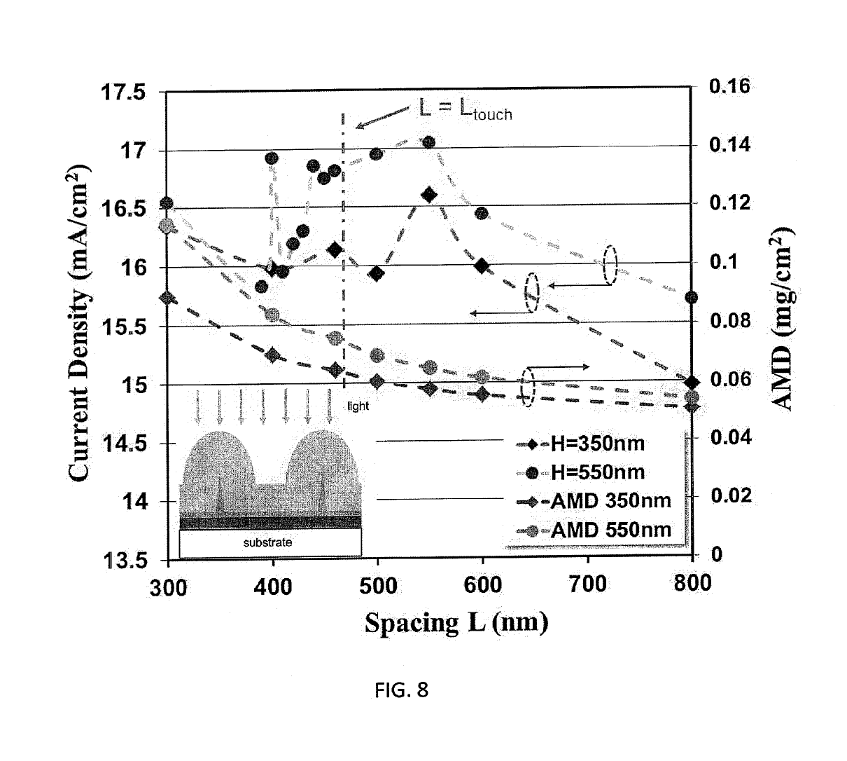

Configuration 3 is the same as Configuration 1 except the AZO nano-elements are now cone-shaped. As is the case for Configuration 1, these nano-elements are positioned on a layer composed of 30 nm of AZO on planar Ag. Configuration 3 is similar to that studied in Ref. 2 except the structure of that reference has an Ag coating over the nano-cones. The A(λ) for this architecture (not plotted) again has variations in its magnitude and Fabry-Perot peak positions which depend on L thereby demonstrating the importance of the geometrical scattering. The resulting J_{SC} as a function of L is given from simulation studies in FIG. 8. The data are shown for two values of the cone-shaped element height H (350 and 550 nm) to convey the roll of this parameter in device performance. Because two H values have been examined, there are two corresponding AMD plots in FIG. 8.

The general behavior of J_{SC} as a function of L for L>L_{touch} in FIG. 8 is essentially that seen in FIGS. 6 and 7. Again the fact that J_{SC} increases for certain L values indicates that scattering among domes is playing a role in this L>L_{touch} range. FIG. 8 shows that J_{SC} exceeds the 200 nm and 750 nm thick planar absorber control values over much of the L range and can attain at least 17.1 mA/cm² with the Configuration 3 architecture. Using the J_{SC} and AMD data for Configuration 3 and the controls allows us to determine that the peak J_{SC}=17.1 mA/cm² in FIG. 8, which occurs for the taller nano-element case, is 56% larger than the J_{SC} attainable with the 200 nm thick planar absorber control. The LCCM device giving rise to this peak uses only 48% more a-Si:H than that used in the 200 nm control. Again we point out that the 750 nm thick planar absorber control has a 28% increase in J_{SC} compared to than that attainable with the 200 nm thick planar absorber control but uses 275% more a-Si:H. Consideration of the geometry in FIG. 8 makes another interesting point: this enhanced LCCM optical performance is attained while keeping all the photocarries within 224 nm of an electrode; i.e., well within a collection length.

### EXAMPLE 6

Multi-junction superstrate and substrate LCCM cells are composed of some combination of two or more p-n, p-i-n, or surface barrier junctions and offer the following: (1) superstrate or substrate configurations; (2) inter-cell electrical and optical matching structures which may comprise (a) a tunnel junction structure, (b) a tunnel junction and Bragg stack reflector structure, and (c) a tunnel junction and a plasmonic reflector; and (3) hybrid configurations using both an LCCM cell or cells and using a planar cell or cells.

An example of this last design is a substrate tandem cell composed of a LCCM top a-Si:H p-i-n cell such as that seen in the inset of FIG. 7 positioned on top of a bottom planar p-i-n nc-Si cell, This example structure uses the nano-element array in the top cell only. FIG. 7 shows that a single junction LCCM cell with only a 200 nm a-Si:H absorber can generate a short circuit current density of 17.3 mA/cm². A planar nc-Si cell positioned under the LCCM a-Si:H cell can match this current density of the top cell by using a nc-Si absorber thickness in the 1000 nm to 1500 nm range. If we take typical a-Si:H and nc-Si open circuit and fill factor values of V_{OC}=0.86 eV and FF=0.63 for a-Si:H cells and V_{OC}=0.54 eV and FF=0.77 for nc-Si, then this LCCM/planar tandem design with short circuit current density of 17 mA/cm² should have a power conversion efficiency (PCE) of about 16.6% (assuming V_{OC}=1.4 eV and FF=0.7). It is important to realize that this will be a stable tandem and will not degrade appreciably since the a-Si:H layer is so thin.

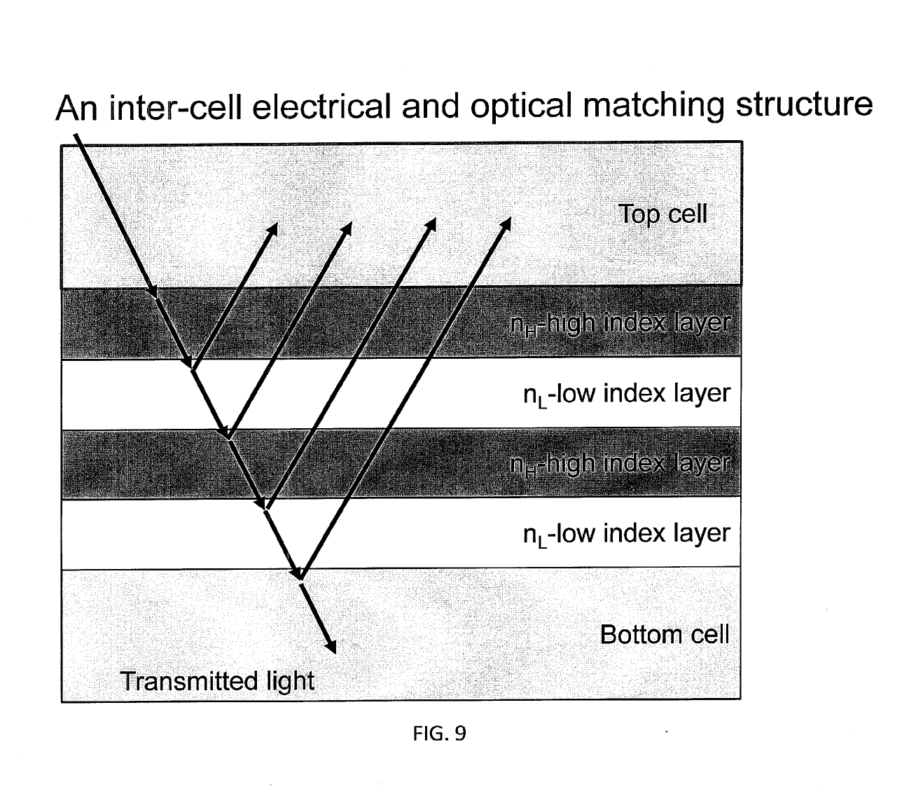

The inter-cell interface region of the example just discussed may utilize a Bragg stack reflector (i.e., a Bragg minor), a plasmonic reflector, or no reflector. FIG. 9 shows the case where the inter-cell region contains a Bragg stack reflector designed to reflect light within a bandwidth centered on λ back into a top cell. The geometrical thicknesses of the high- and low-index films are t_{H}=λ/(4 n_{H}) and t_{L}=λ/(4 n_{L}) respectively. Here n_{H} and n_{L}, are the indices of refraction of the high- and low-index films, respectively. For the example of an LCCM a-Si:H cell on planar nc-Si cell, this Bragg structure can be taken to have high n layer to be a-Si:H with n_{H}˜4 and the low n layer to be a TCO with n_{H}˜2, therefore t_{H}˜38 nm and t_{L}˜76 nm if λis taken to be 600 nm. A λ of about this wavelength is selected because photons in the 500 nm to 700 nm range can make it through the a-Si:H to the bottom cell even though they are supra-band gap photons in the a-Si:H. Consequently, in this example tandem, photons in this wavelength range need to be reflected back into the top cell. This inter-cell structure could also function as a part of the tunneling interface between the two cells. For example, if photogenerated electrons are coming to the inter-cell region from the top a-Si:H cell, then the first high n layer could be doped to be a n+/p+ tunnel junction and the last low n layer could be a TCO contact to the p+ contact of the bottom nc-Si cell.

### EXAMPLE 7

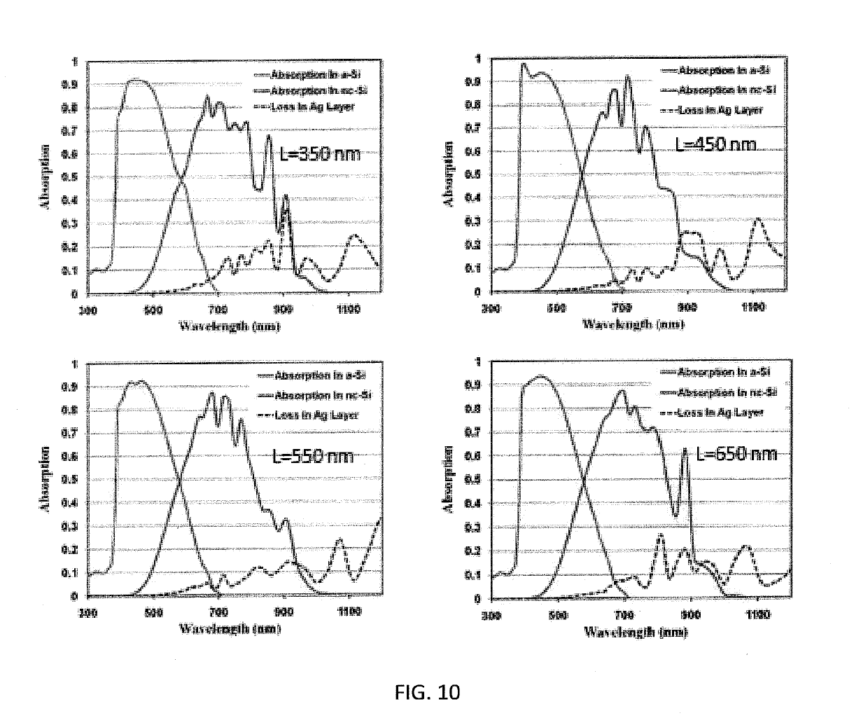

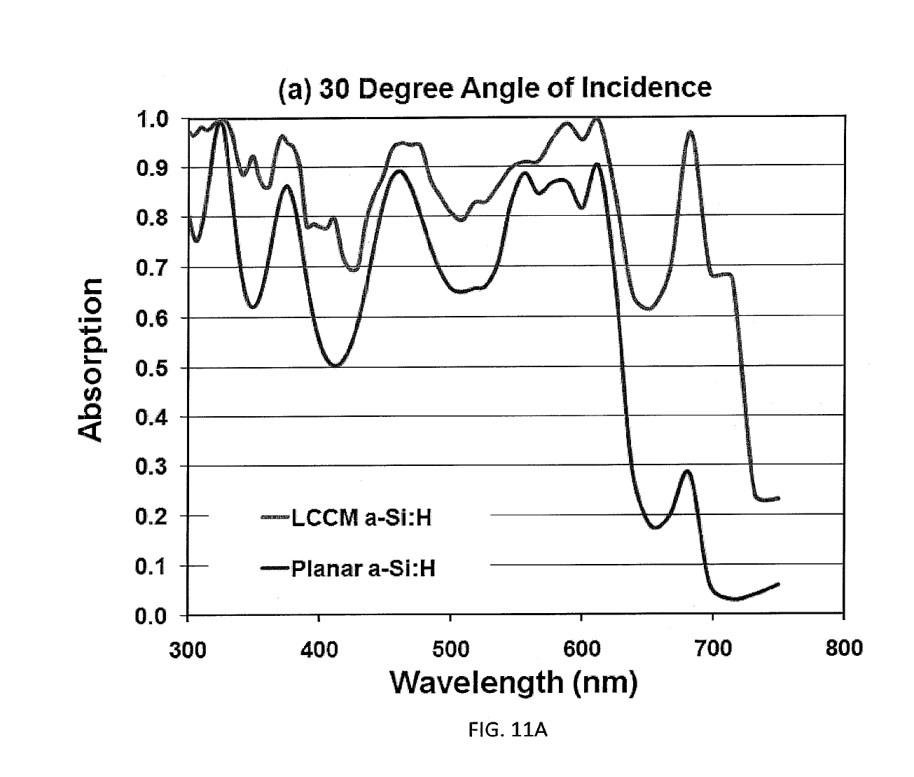

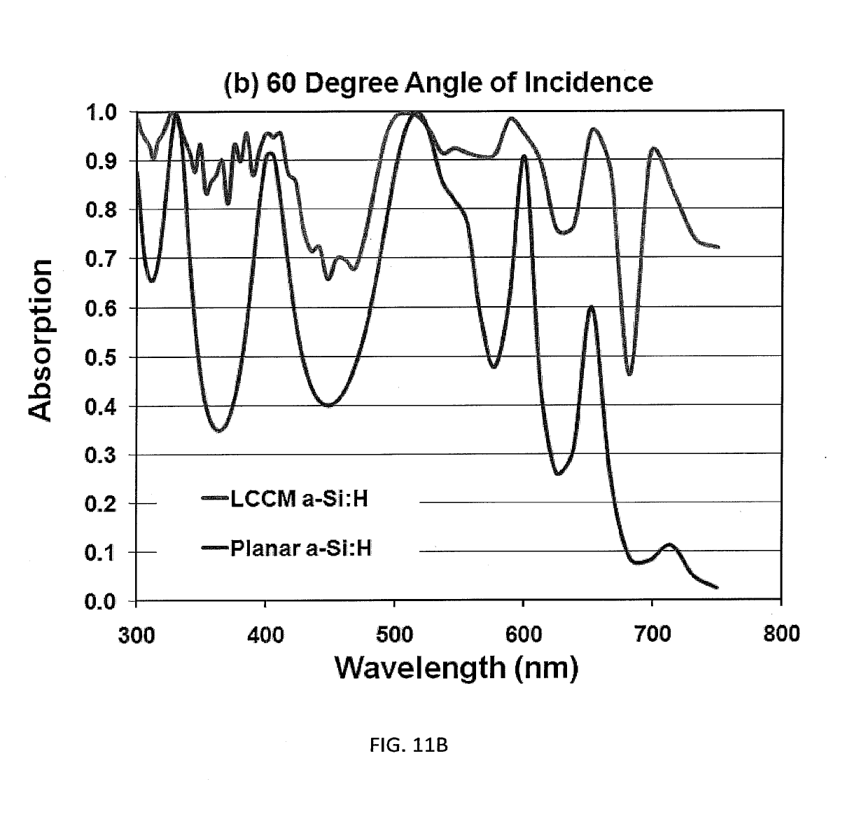

FIG. 4 shows an a-Si:H on nc-Si LCCM tandem example in which both the top and bottom cells are non-planar due to the use of a nano-element array in the bottom cell. In modeling of this structure we took the electrical and optical matching structure to have a thin (5 nm Ag) metal layer as a plasmonic reflector. The absorption data of several different nano-element spacings are shown for the cell of FIG. 4 in FIG. 10. As may be noted from FIG. 10 too much of the light in the range from ˜500 to 600 nm is surviving to enter into the bottom cell and being absorbed there. Light in this range has photons above the a-Si:H band gap and should be adsorbed in the top a-Si:H cell The photonic reflector must be adjusted to reflect this light back into the top cell effectively. Alternatively, a Bragg reflector-type structure could be utilized in the inter-cell region. This would be conformally deposited.

Any patents or publications mentioned in this specification are indicative of the levels of those skilled in the art to which the invention pertains. These patents and publications are herein incorporated by reference to the same extent as if each individual publication was specifically and individually indicated to be incorporated by reference.

### CITED REFERENCES

1. G. S. Kinsey, P. Pien, P. Hebert, and R. A. Sherif, “Operating characteristics of multijunction solar cells,” Solar Energy Materials & Solar Cells 2009, 93, 950.
2. (a) T. Takamoto, K. Sasaki, T. Agui, H. Juso, A. Yoshida, and K. Nakaido, “III-V compound solar cells,” SHARP Technical Journal 2010, 100, 1; (b) http://sharp-world.com/corporate/news/091022.html
3. S. Fonash, Solar Cell Device Physics, 2^{nd} Edition, Elsevier, Hoboken, N.J., 2010.
4. B. Yan, G. Yue, and S. Guha, “Status of nc-Si:H solar cells at united solar and roadmap for manufacturing a-Si:H and nc-Si:H based solar panels,” Mater. Res. Soc. Symp. Proc. 2007, 989, 0989-A15-01.
5. T. Matsui, H. Jia, and M. Kondo, “Thin film solar cells incorporating rnicrocrystalline Si(1-x)Ge(x) as efficient infrared absorber: An application to double junction tandem solar cells,” Prog. Photovolt: Res. Appl. 2010, 18, 48.
6. S. Schicho, Hrunski, R. van Aubel, and A. Gordijn, “High potential of thin (<1 mm) a-Si:H/mc-Si:H tandem solar cells,” Prog. Photovolt: Res. Appl. 2010, 18, 83.
7. M. W. Wang, “Novel CdSe-based PV structure for high efficiency CdSe/CIGS tandem solar cells,” IEEE 34^{th} Photovoltaic Specialists Conference, Philadelphia, Pa., Jun. 7-12, 2009.
8. W. J. Nam, T. Liu, S. Wagner, and S. Fonash, “A study of lateral collection single junction a-Si:H solar cell devices using nano-scale columnar array,” IEEE 35^{th} Photovoltaic Specialists Conference, Honolulu, Hi, June, Jun. 20-25, 2010.
9. J. Zhu, C. M. Hsu, Z. Yu, S. Fan, Y. Cui, Nano Lett., 10, 1979 (2010).

1. A superstrate device comprising:
a planar electrode;
an array of conducting nano-elements in electrical and physical contact with said planar electrode;
a spacer of 0 to 100 nm in thickness in contact with said array of conducting nano-elements;
a volume region comprised of at least one light absorbing material in simultaneous contact with said spacer have periodic undulations;
a distal reflecting counter electrode relative to the direction of impinging light;
wherein said photovoltaic device enhances trapping of the impinging light and photocarrier collection throughout the absorber volume regions.

2. The substrate device of claim 1 wherein said planar electrode comprises a reflecting material.

3. The superstrate device of claim 1 wherein
volume region comprised of the at least one light absorbing material.

4. The substrate device of claim 1 wherein said
planar electrode comprises a reflecting material; and the
volume region comprised of the at least one light absorbing material in simultaneous contact with said spacer to form an single junction photovoltaic device with the periodic undulations;
wherein said photovoltaic device enhances trapping of the impinging light and photocarrier collection throughout the absorber volume regions.

5. The superstrate device of claim 1 further comprising at least one more volume region comprised of at least one light absorbing material with the first in simultaneous contact with said spacer and each volume region integral to a cell, a tunneling junction between each of these cells, the cells constituting a multi junction device with the periodic undulations.

6. A substrate device comprising:
a planar electrode comprising a reflecting material;
an array of conducting nano-elements in electrical and physical contact with said planar electrode;
a spacer of 0 to 100 nm in thickness in contact with said array of conducting nano-elements;
two or more volume regions comprised of at least one light absorbing material with the first in simultaneous contact with said spacer and each volume region integral to a cell,
a tunneling junction between each of these cells,
the cells constituting the multi junction device with periodic undulations;
wherein said photovoltaic device enhances trapping of the impinging light and photocarrier collection throughout the absorber volume regions.

7. A hybrid device comprising:
a planar cell
an array of conducting nano-elements in electrical and physical contact with a planar interface region adjacent to said planar cell;
a spacer of 0 to 100 nm in thickness in contact with said array of conducting nano-elements;
one or more volume regions comprised of at least one light absorbing material with the first in simultaneous contact with said spacer and each volume region integral to a cell,
to form an operating multi junction photovoltaic device having a plurality of cells;
a tunneling junction between each of the cells constituting the multi-junction device;
said cells having periodic undulations in said multi junction photovoltaic device except in the planar cell and in the planar interface region, wherein said multi junction photovoltaic device enhances trapping of the impinging light and photocarrier collection.
